(19) United States
(12) Patent Application Publication
(10) Pub. No.: US 2026/0130151 A1
(43) Pub. Date: May 7, 2026

(54) METHOD FOR MANUFACTURING BONDING STRUCTURE AND BONDING STRUCTURE MANUFACTURED USING THE SAME

(71) Applicant: Samsung Electronics Co., Ltd., Suwon-si (KR)

(72) Inventors: Dong-Chan LIM, Suwon-si (KR); Seok Ho KIM, Suwon-si (KR); Ho-Jin LEE, Suwon-si (KR); Joo Hee JANG, Suwon-si (KR)

(73) Assignee: Samsung Electronics Co., Ltd., Suwon-si (KR)

(21) Appl. No.: 19/211,461

(22) Filed: May 19, 2025

(30) Foreign Application Priority Data
Nov. 4, 2024 (KR) 10-2024-0154138

(51) Int. Cl. H01L 21/304; H01L 23/00

(52) U.S. Cl. CPC H10P 52/00; H10W 80/312; H10W 80/327

(57) ABSTRACT

A method includes providing a first substrate structure including a first semiconductor substrate having first and second surfaces opposite to each other, and a first semiconductor device layer on the first surface, providing a second substrate structure including a second semiconductor substrate having third and fourth surfaces opposite to each other, and a second semiconductor device layer on the third surface, removing a portion of the second semiconductor device layer on a first edge region of the second semiconductor substrate, electrically connecting the first and second semiconductor device layers by bonding the first and second substrate structures such that the first surface faces the third surface, forming a gap-filling film that fills a portion of a gap between the first substrate structure and the first edge region, removing a portion of the first edge region and reducing the thickness of the second semiconductor substrate using a laser trimming process.

### CROSS-REFERENCE TO RELATED APPLICATION

This U.S. non-provisional application claims priority under 35 U.S.C. 119 to Korean Patent Application No. 10-2024-0154138 filed on Nov. 4, 2024, in the Korean Intellectual Property Office, the contents of which are herein incorporated by reference in their entirety.

### BACKGROUND

Example embodiments relate to a method for manufacturing a bonding structure using a trimming process for wafer bevels, and a bonding structure manufactured using the method.

Semiconductor chips (or semiconductor integrated circuits (ICs)) are fabricated on semiconductor substrates (e.g., wafers) using semiconductor manufacturing processes such as photolithography, etching, deposition, and ion implantation. As the thickness of semiconductor chips decreases, bevels, which may refer to inclined surfaces formed at the edges of semiconductor substrates, may cause stress at the edges of the semiconductor substrates, and may cause defects such as cracks and/or delamination. Accordingly, it is advantageous to trim the edges of semiconductor substrates including the bevels.

### SUMMARY

Example embodiments are directed to a method for manufacturing a bonding structure with improved productivity.

Example embodiments are also directed to a bonding structure with improved productivity.

The technical problems of the present disclosure are not limited to those mentioned above, and other technical problems not explicitly described can be clearly understood by those skilled in the art from the description below.

However, example embodiments are not restricted to those set forth herein. The above and other aspects of the example embodiments will become more apparent to one of ordinary skill in the art to which the present disclosure pertains by referencing the detailed description of the present disclosure given below.

According to some example embodiments, a method for manufacturing a bonding structure includes providing a first substrate structure including a first semiconductor substrate having a first surface and a second surface that are opposite to each other, and a first semiconductor device layer on the first surface, providing a second substrate structure including a second semiconductor substrate having a third surface and a fourth surface that are opposite to each other, and a second semiconductor device layer on the third surface, removing a portion of the second semiconductor device layer disposed on a first edge region of the second semiconductor substrate, bonding the first and second substrate structures such that the first surface faces the third surface, forming a gap-filling film that fills at least a portion of a gap between the first substrate structure and the first edge region and performing a trimming process to remove at least a portion of the first edge region, after the forming the gap-filling film.

According to some example embodiments, a method for manufacturing a bonding structure includes providing a first substrate structure including a first semiconductor substrate having a first surface and a second surface that are opposite to each other, and a first semiconductor device layer on the first surface, providing a second substrate structure including a second semiconductor substrate having a third surface and a fourth surface that are opposite to each other, and a second semiconductor device layer on the third surface, removing a portion of the second semiconductor device layer disposed on a first edge region of the second semiconductor substrate, electrically connecting the first and second semiconductor device layers by bonding the first and second substrate structures such that the first surface faces the third surface, forming a gap-filling film that fills at least a portion of a gap between the first substrate structure and the first edge region, performing a laser trimming process to remove at least a portion of the first edge region, after the forming the gap-filling film and performing a thinning process to reduce a thickness of the second semiconductor substrate, after performing the laser trimming process, wherein a coefficient of thermal expansion (CTE) of the gap-filling film is greater than a CTE of the second semiconductor substrate.

According to some example embodiments, a method for manufacturing a bonding structure includes providing a first substrate structure including a first semiconductor substrate having a first surface and a second surface that are opposite to each other, and a first semiconductor device layer on the first surface, removing a portion of the first semiconductor device layer disposed on a first edge region of the first semiconductor substrate, providing a second substrate structure including a second semiconductor substrate having a third surface and a fourth surface that are opposite to each other, and a second semiconductor device layer on the third surface, removing a portion of the second semiconductor device layer disposed on a second edge region of the second semiconductor substrate, electrically connecting the first and second semiconductor device layers by bonding the first and second substrate structures such that the first surface faces the third surface, forming a gap-filling film that fills at least a portion of a gap between the first and second edge regions, performing a trimming process to remove at least a portion of the second edge region, after the forming the gap-filling film and performing a thinning process to reduce a thickness of the second semiconductor substrate, after the performing the trimming process.

According to some example embodiments, a semiconductor device includes a first substrate structure including a first semiconductor substrate having a first surface and a second surface opposite to each other, and a first semiconductor device layer on the first surface, and a second substrate structure including a second semiconductor substrate having a third surface and a fourth surface opposite to each other, and a second semiconductor device layer on the third surface, wherein the second semiconductor device layer is directly on the first semiconductor device layer and is electrically connected to the first semiconductor device layer. In some example embodiments, side surfaces of the first semiconductor device layer and the second semiconductor device layer are coplanar. In some example embodiments, a side surface of the first semiconductor device layer defines a first acute angle with respect to the first surface, and a side surface of the second semiconductor device layer defines a second acute angle with respect to the third surface. In some example embodiments, a side surface of the first semiconductor device layer extends horizontally from a side surface of the second semiconductor device layer. In some example embodiments, a side surface of the second semiconductor device layer extends horizontally from a side surface of the first semiconductor device layer.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIGS. 1, 2, 3, 4, 5, 6, 7, 8, 9, 10, and 11 are diagrams illustrating intermediate operations in a method for manufacturing a bonding structure according to some example embodiments.

FIGS. 12, 13, 14, and 15 are diagrams illustrating intermediate operations in a method for manufacturing a bonding structure according to some example embodiments.

FIGS. 16 and 17 are diagrams illustrating intermediate operations in a method for manufacturing a bonding structure according to some example embodiments.

FIGS. 18, 19, 20, and 21 are diagrams illustrating intermediate operations in a method for manufacturing a bonding structure according to some example embodiments.

FIGS. 22, 23, and 24 are diagrams illustrating semiconductor devices including different bonding structures according to some example embodiments.

### DETAILED DESCRIPTION

In the drawings, the thickness of layers, films, panels, regions, etc., are exaggerated for clarity.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

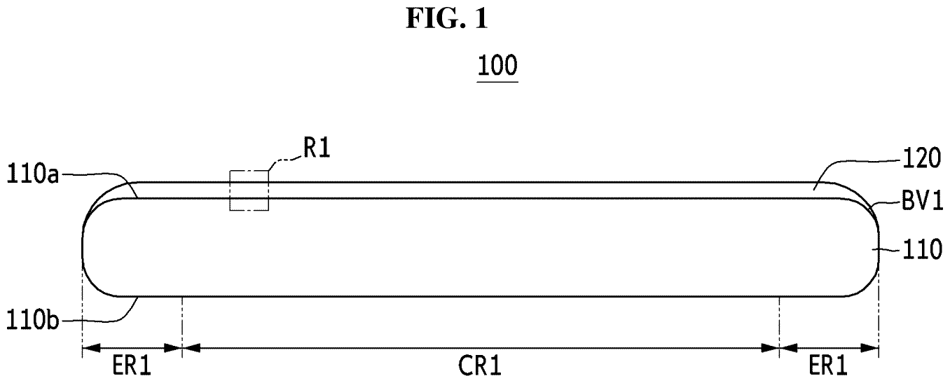

A method for manufacturing a bonding structure according to some example embodiments and a bonding structure manufactured using the method will hereinafter be described with reference to FIGS. 1 through 24.

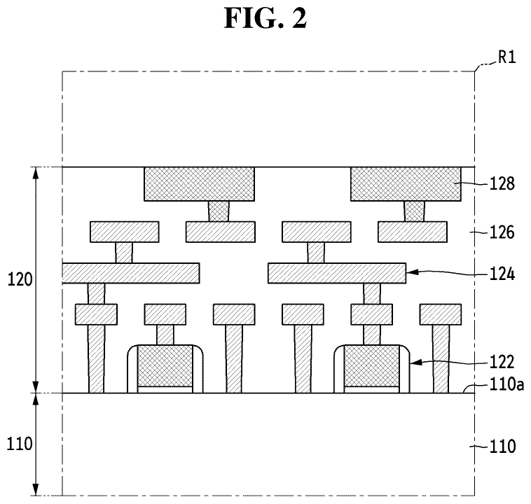

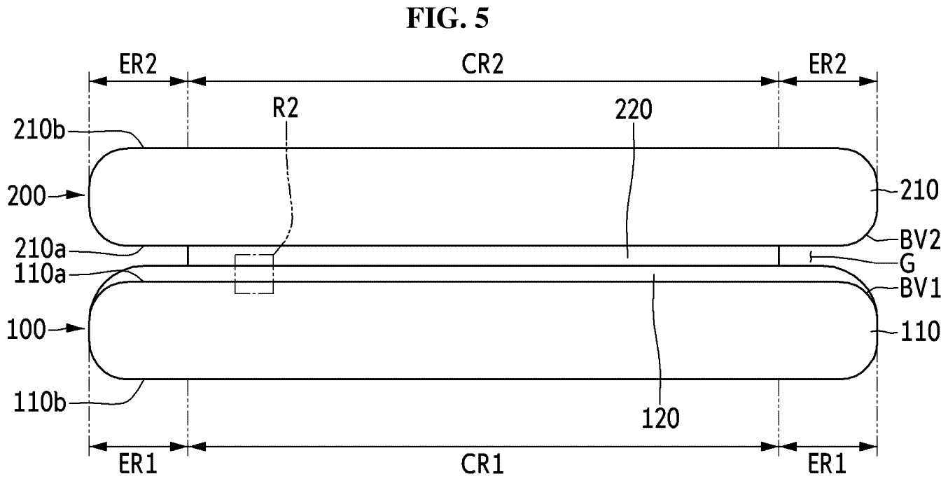

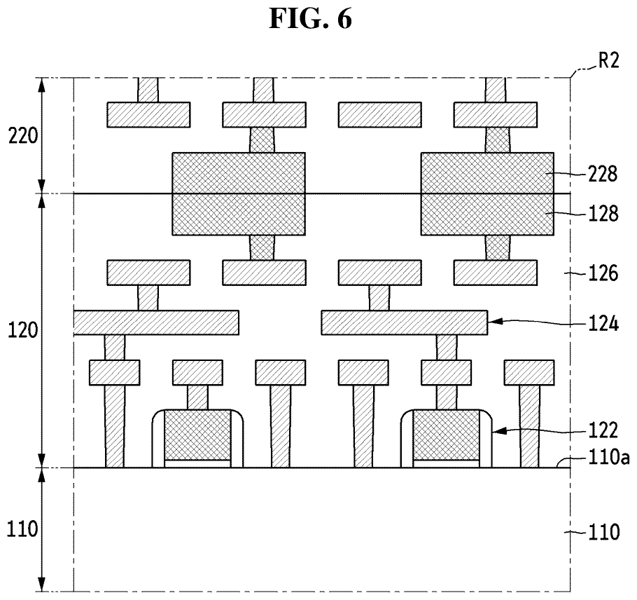

FIGS. 1 through 11 are diagrams illustrating intermediate operations in a method for manufacturing a bonding structure according to some example embodiments. FIG. 2 is an enlarged view illustrating region R1 of FIG. 1, and FIG. 6 is an enlarged view illustrating region R2 of FIG. 5.

Referring to FIGS. 1 and 2, a first substrate structure 100 may include a first semiconductor substrate 110 and a first semiconductor device layer 120.

The first semiconductor substrate 110 may be, for example, bulk silicon or silicon-on-insulator (SOI). The first semiconductor substrate 110 may be a silicon substrate, or may include other materials such as silicon germanium, indium antimonide, a lead telluride compound, indium arsenide, indium phosphide, gallium arsenide, or gallium antimonide. Alternatively, the first semiconductor substrate 110 may have an epitaxial layer formed on a base substrate.

The first semiconductor substrate 110 may include a first surface 110a and a second surface 110b that are opposite to each other. The first surface 110a may be referred to as an active surface where semiconductor devices are formed. For example, the first surface 110a may include conductive regions, such as impurity-doped wells. Additionally, the first surface 110a may include isolation regions, for example, various device isolation structures such as shallow trench isolations (STIs).

The first semiconductor substrate 110 may include a first central region CR1 and a first edge region ER1. The first edge region ER1 may be defined along the periphery of the first central region CR1. In some example embodiments, the first edge region ER1 may correspond to the edge portion (e.g., outer edge portion) of the first semiconductor substrate 110. The first edge region ER1 may include (or otherwise, define) a first bevel BV1 that is inclined with respect to the first surface 110a and/or the second surface 110b.

The first semiconductor device layer 120 may be formed on the first surface 110a of the first semiconductor substrate 110. The first semiconductor device layer 120 may include different types of individual devices and/or interlayer insulating films. The individual devices may include, but are not limited to, various microelectronic devices, such as metal-oxide-semiconductor field-effect transistors (MOSFETs) (e.g., CMOS transistors), system large-scale integrations (LSIs), flash memories, DRAMs, SRAMs, EEPROMs, PRAMs, MRAMs, RRAMs, image sensors (e.g., CMOS imaging sensors), micro-electro-mechanical systems (MEMSs), active devices, passive devices, etc.

In some example embodiments, the first semiconductor device layer 120 may extend along at least a portion of the first bevel BV1.

The first semiconductor device layer 120 may include a circuit pattern 122, a wiring structure 124, and an inter-wiring insulating film 126.

The circuit pattern 122 may include, for example, transistors, but is not limited thereto. For example, the circuit pattern 122 may include various active elements such as transistors, and various passive elements such as capacitors, resistors, and inductors.

The wiring structure 124 and the inter-wiring insulating film 126 may be formed on the circuit pattern 122. The wiring structure 124 may be formed within the inter-wiring insulating film 126. The wiring structure 124 may be electrically connected to the circuit pattern 122. For example, the wiring structure 124 may include wiring patterns of a multilayer structure and via patterns interconnecting the wiring patterns. The wiring patterns and via patterns of the wiring structure 124 may be electrically insulated from each other by the inter-wiring insulating film 126. The arrangement, number of layers of wiring structures 124, and number of the wiring structures 124 in one or more layers as illustrated in FIG. 2 are merely illustrative and are not limiting.

In some example embodiments, the first semiconductor device layer 120 may include a first bonding pattern 128. The first bonding pattern 128 may be formed on the uppermost metal layer of the wiring structure 124. The first bonding pattern 128 may be exposed from the upper surface of the inter-wiring insulating film 126.

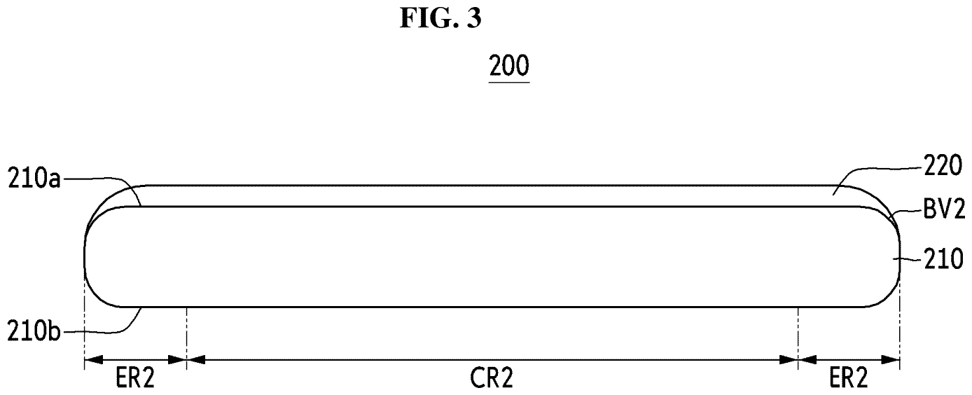

Referring to FIG. 3, a second substrate structure 200 may include a second semiconductor substrate 210 and a second semiconductor device layer 220.

The second semiconductor substrate 210 may be, for example, bulk silicon or SOI. The second semiconductor substrate 210 may be a silicon substrate, or may include other materials such as silicon germanium, indium antimonide, a lead telluride compound, indium arsenide, indium phosphide, gallium arsenide, or gallium antimonide. Alternatively, the second semiconductor substrate 210 may have an epitaxial layer formed on a base substrate.

The second semiconductor substrate 210 may include a third surface 210a and a fourth surface 210b that are opposite to each other. The third surface 210a may be referred to as an active surface where semiconductor devices are formed. For example, the third surface 210a may include conductive regions, such as impurity-doped wells. Additionally or alternatively, the third surface 210a may include isolation regions, for example, various device isolation structures such as STIs.

The second semiconductor substrate 210 may include a second central region CR2 and a second edge region ER2. The second edge region ER2 may be defined along the periphery of the second central region CR2. In other words, the second edge region ER2 may correspond to the edge portion (e.g., outer edge portion) of the second semiconductor substrate 210. The second edge region ER2 may include (or otherwise, define) a second bevel BV2 that is inclined with respect to the third surface 210a and/or the fourth surface 210b.

The second semiconductor device layer 220 may be formed on the third surface 210a of the second semiconductor substrate 210. The second semiconductor device layer 220 may include different types of individual devices and/or interlayer insulating films. The second semiconductor device layer 220 may be same as or similar in some respects to the first semiconductor device layer 120 and therefore will be best understood with reference thereto.

In some example embodiments, the second semiconductor device layer 220 may extend along at least a portion of the second bevel BV2.

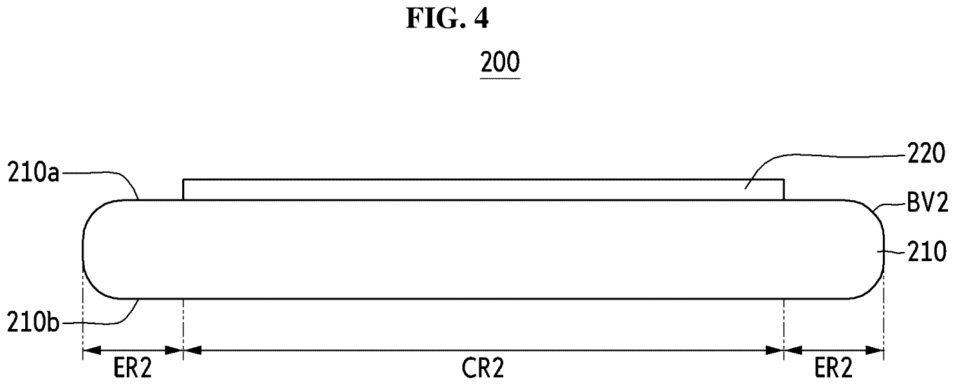

Referring to FIG. 4, a portion of the second semiconductor device layer 220 disposed on the second edge region ER2 is removed.

For example, the edge of the second semiconductor device layer 220 disposed on the second edge region ER2 may be removed, exposing the second edge region ER2 from the second semiconductor device layer 220. In some example embodiments, the removal of a portion of the second semiconductor device layer 220 may be performed using a photolithography process and/or a plasma etching process. For example, the removal of a portion of the second semiconductor device layer 220 may involve at least one of an edge exclusion width (EEW) process, an edge bead removal (EBR) process, or a plasma enhanced strip (PES) process.

Referring to FIGS. 5 and 6, the first and second substrate structures 100 and 200 are bonded together.

The first and second substrate structures 100 and 200 may be bonded such that the first and third surfaces 110a and 210a may face each other. For example, the first semiconductor device layer 120 of the first substrate structure 100 and the second semiconductor device layer 220 of the second substrate structure 200 may be directly bonded. Through this, a bonding structure including the first and second substrate structures 100 and 200 may be provided.

Before the bonding of the first and second substrate structures 100 and 200, as the portion of the second semiconductor device layer 220 disposed on the second edge region ER2 is removed, a gap G may be formed or otherwise defined between the first substrate structure 100 and the second edge region ER2. For example, the gap G may be formed or defined between a portion of the first semiconductor device layer 120 on the first edge region ER1 and the second edge region ER2. Additionally, the gap G may be defined on the side surface of a portion of the second semiconductor device layer 220 that remains on the second central region CR2.

In some example embodiments, the bonding structure may have a chip-to-chip (C2C) structure. The C2C structure refers to a scheme where the first semiconductor device layer 120 is fabricated on a first wafer (e.g., the first semiconductor substrate 110) and the second semiconductor device layer 220 is fabricated on a second wafer (e.g., the second semiconductor substrate 210), and the first and second semiconductor device layers 120 and 220 are interconnected through bonding.

This bonding method may involve, for example, connecting a first bonding pattern 128 formed on the uppermost metal layer of the first semiconductor device layer 120 and a second bonding pattern 228 formed on the uppermost metal layer of the second semiconductor device layer 220. For example, when the first and second bonding patterns 128 and 228 are formed of copper (Cu), the bonding method may be referred to as a Cu—Cu bonding method. However, this is merely example, and the first and second bonding patterns 128 and 228 may also be formed of other metals such as aluminum (Al) or tungsten (W). By bonding the first and second bonding patterns 128 and 228, the first and second semiconductor device layers 120 and 220 may be electrically connected.

In some example embodiments, the first semiconductor device layer 120 may include a peripheral circuit of a semiconductor memory chip, and the second semiconductor device layer 220 may include a memory cell array of a semiconductor memory chip. By bonding the first substrate structure 100 and the second substrate structure 200, the peripheral circuit of the first semiconductor device layer 120 may be electrically connected to the memory cell array of the second semiconductor device layer 220.

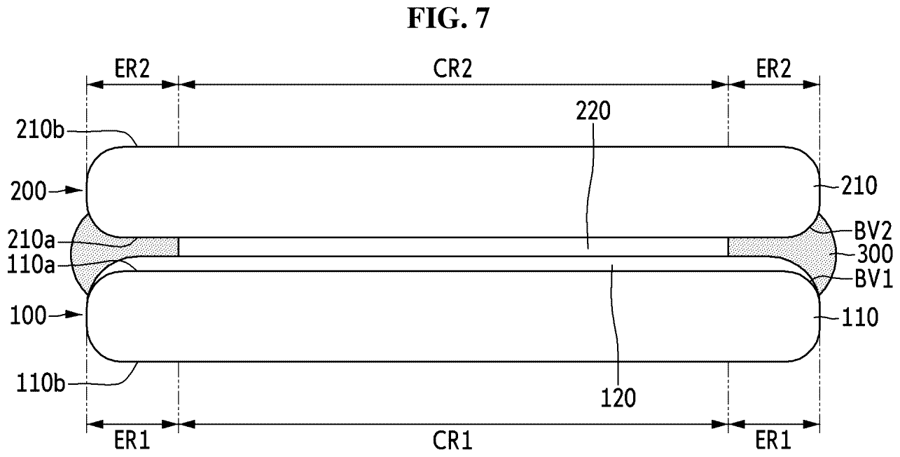

Referring to FIG. 7, a gap-filling film 300 is formed.

The gap-filling film 300 may fill at least a portion of the gap G illustrated in FIG. 5. For example, at least a portion of the gap-filling film 300 may be positioned between the first substrate structure 100 and the second edge region ER2. In some example embodiments, the gap-filling film 300 may contact the upper surface of the first semiconductor device layer 120, the side surface of the second semiconductor device layer 220, and the third surface 210a of the second semiconductor substrate 210. In some example embodiments, the gap-filling film 300 may further contact the second bevel BV2.

The gap-filling film 300 may include a material different from that of the second semiconductor substrate 210. In some example embodiments, the coefficient of thermal expansion (CTE) of the gap-filling film 300 may differ from that of the second semiconductor substrate 210. For example, the CTE of the gap-filling film 300 may be greater than that of the second semiconductor substrate 210. For example, when the second semiconductor substrate 210 includes monocrystalline silicon, the gap-filling film 300 may include polycrystalline silicon.

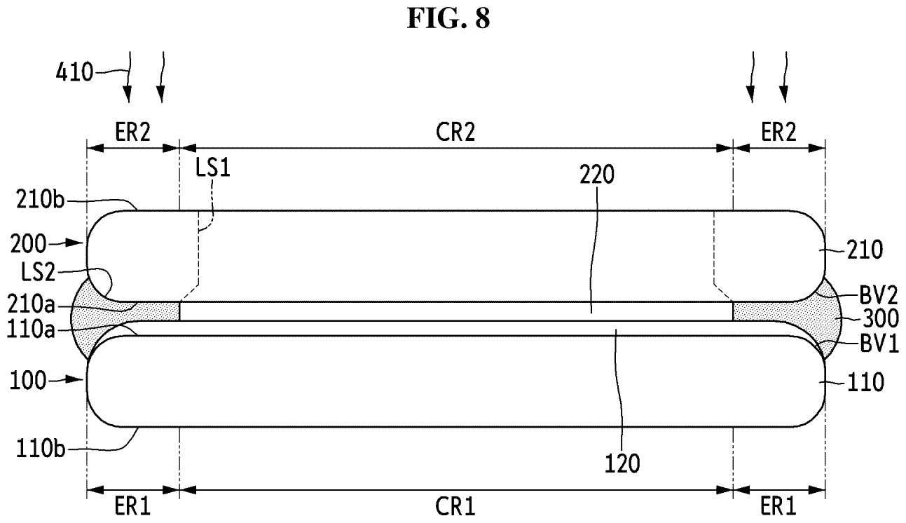

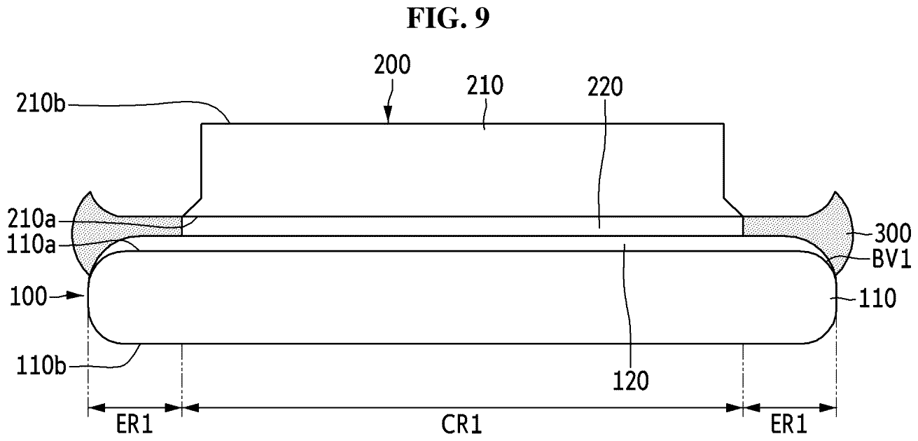

Referring to FIGS. 8 and 9, a trimming process is performed on the second edge region ER2.

As the trimming process is performed, at least a portion of the second edge region ER2, including the second bevel BV2, may be removed. In some example embodiments, the trimming process may include a laser trimming process. For example, laser light 410 may be irradiated onto the second edge region ER2, including the second bevel BV2.

In some example embodiments, the laser trimming process may utilize different first and second laser light sources.

For example, the first laser light source may be used to separate the second edge region ER2 from the second central region CR2. As the laser light 410 is irradiated using the first laser light source, a first boundary LS1 may be formed or defined between the second central region CR2 and the second edge region ER2. The second edge region ER2 may then be separated from the second central region CR2 based on the first boundary LS1.

Similarly, the second laser light source may be used to separate the second edge region ER2 from the gap-filling film 300. As the laser light 410 is irradiated using the second laser light source, a second boundary LS2 may be formed or defined between the second edge region ER2 and the gap-filling film 300. The second edge region ER2 may then be separated from the gap-filling film 300 based on the second boundary LS2. In some example embodiments, the second laser light source may separate the second edge region ER2 from the gap-filling film 300 using (or based on) the CTE difference between the second semiconductor substrate 210 and the gap-filling film 300.

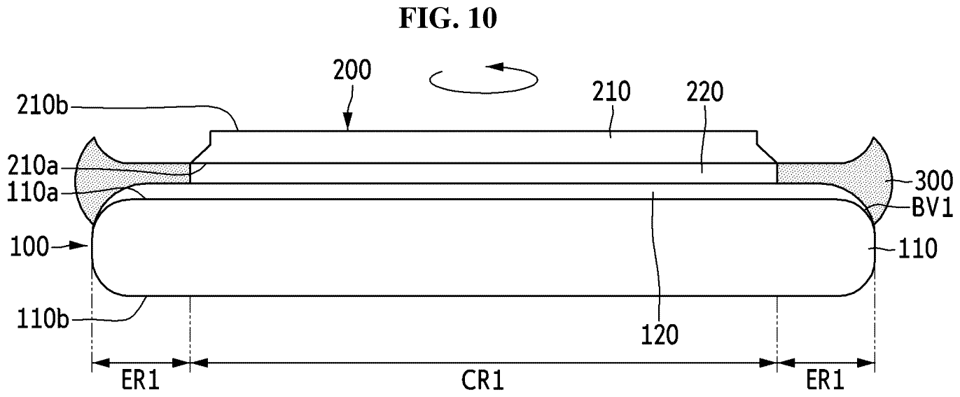

Referring to FIG. 10, a thinning process is performed on the second semiconductor substrate 210.

The thinning process may include, for example, a back-grinding process for the second surface 110b but is not limited thereto. As the thinning process is performed, the thickness of the second semiconductor substrate 210 may be reduced.

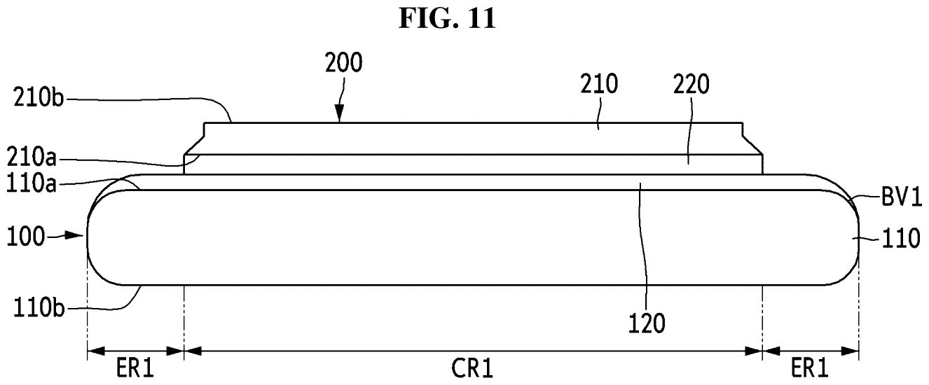

Referring to FIG. 11, the gap-filling film 300 is removed.

In some example embodiments, the removal of the gap-filling film 300 may be omitted. For example, at least a portion of the gap-filling film 300 may remain on the upper surface of the first substrate structure 100 and/or the side surface of the second semiconductor device layer 220.

To improve process stability and quality, a trimming process referred to as a trim-last process may be performed, in which a trimming process is performed on an upper semiconductor substrate of an upper substrate structure after bonding a lower substrate structure and the upper substrate structure.

In the method for manufacturing a bonding structure according to some example embodiments, the extent of etching of the second semiconductor device layer 220 may be predefined before performing the trimming process, and the etching of the second semiconductor device layer 220 may be better performed and/or controlled during the trim-last process. In some example embodiments, as described above, the portion of the second semiconductor device layer 220 disposed on the second edge region ER2 may be removed in advance, before the first and second substrate structures 100 and 200 are bonded. This may reduce or limit defect formation due to the trim-last process and may provide a bonding structure with improved productivity.

Furthermore, as described above, the gap-filling film 300 may replace the region of the removed second semiconductor device layer 220. The gap-filling film 300 may support the second semiconductor substrate 210 during the trimming process and also protect the first substrate structure 100. This improves process stability and quality, thereby providing a bonding structure with improved productivity.

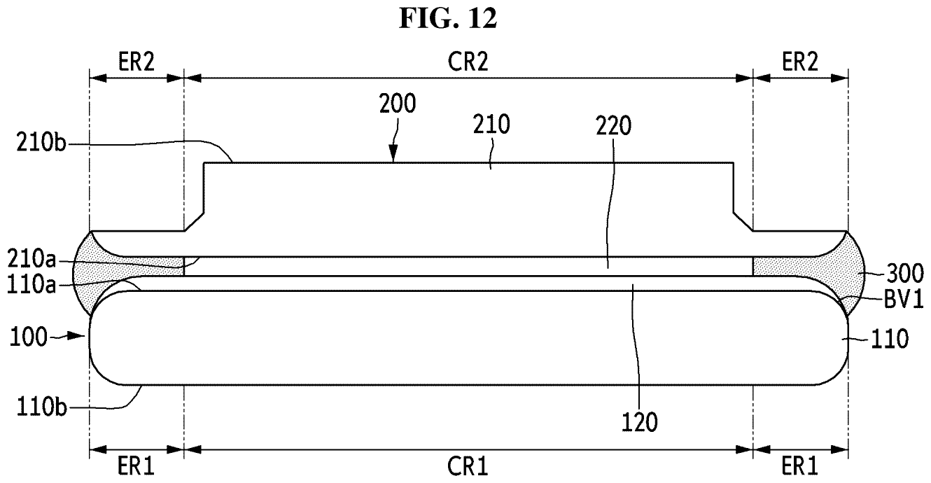

FIGS. 12 through 15 are diagrams illustrating intermediate operations in a method for manufacturing a bonding structure according to some example embodiments. The operations in FIGS. 12-15 may be same as or similar in some respects to the operations described above with reference to FIGS. 1 through 11, and therefore may be best understood with reference thereto where like numerals indicate like elements not described again in detail. In some example embodiments, FIGS. 12 through 15 illustrate operations subsequent to that the operation in FIG. 7.

Referring to FIGS. 7 and 12, after the trimming process is performed, a portion of the second edge region ER2 may be retained.

For example, after the trimming process is performed, at least a portion of the gap-filling film 300 may be positioned between the remaining second edge region ER2 and the first substrate structure 100. The upper surface of the remaining second edge region ER2 is illustrated as being at the same level as the uppermost height of the gap-filling film 300, but this is merely example. Alternatively, the upper surface of the remaining second edge region ER2 may be at a lower or higher level than the uppermost height of the gap-filling film 300 depending on application and/or design.

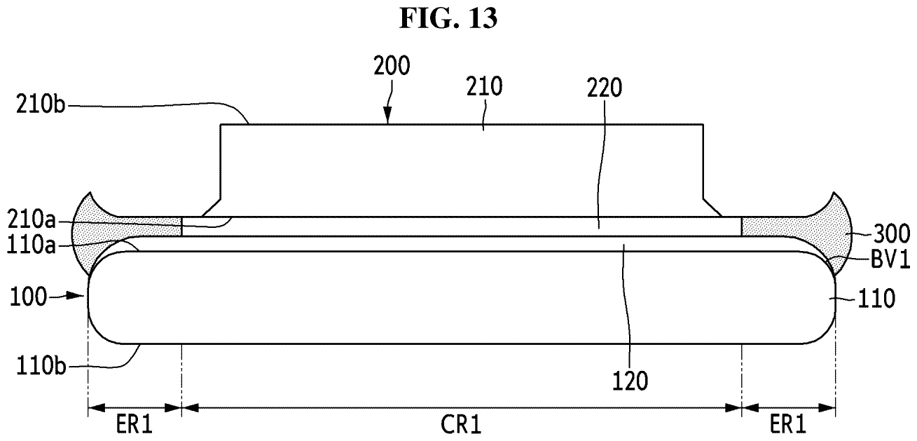

Referring to FIGS. 7 and 13, after the trimming process is performed, a portion of the second semiconductor device layer 220 is exposed from the second semiconductor substrate 210.

For example, after the trimming process is performed, the side surface of the second semiconductor device layer 220 may protrude or extend in a horizontal direction (e.g., a direction parallel to the third surface 210a and/or the fourth surface 210b) relative to the side surface of the second semiconductor substrate 210. In some example embodiments, the size (or area) of the second semiconductor device layer 220 in the horizontal direction may be greater than the size (or area) of the second semiconductor substrate 210.

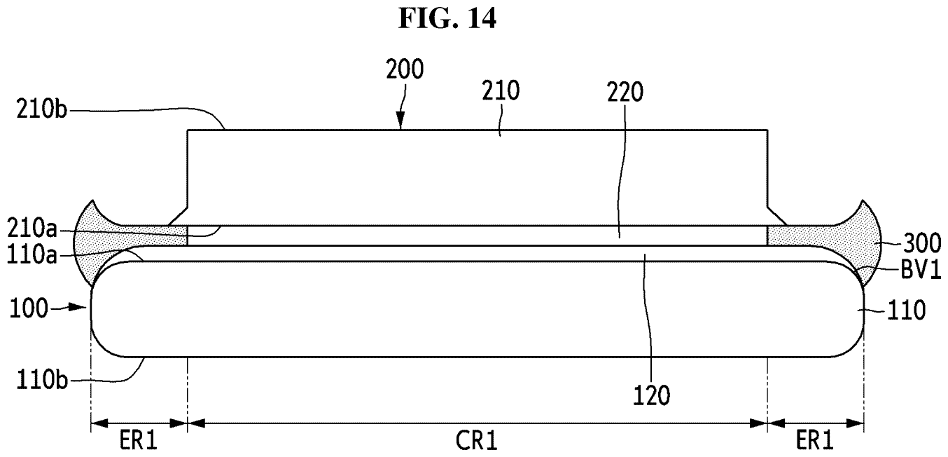

Alternatively, referring to FIGS. 7 and 14, after the trimming process is performed, a portion of the second semiconductor substrate 210 covers part of the gap-filling film 300.

For example, after the trimming process is performed, the side surface of the second semiconductor substrate 210 may protrude or extend in a horizontal direction (e.g., a direction parallel to the third surface 210a and/or the fourth surface 210b) relative to the side surface of the second semiconductor device layer 220. In some example embodiments, the size (or area) of the second semiconductor substrate 210 in the horizontal direction may be greater than the size (or area) of the second semiconductor device layer 220.

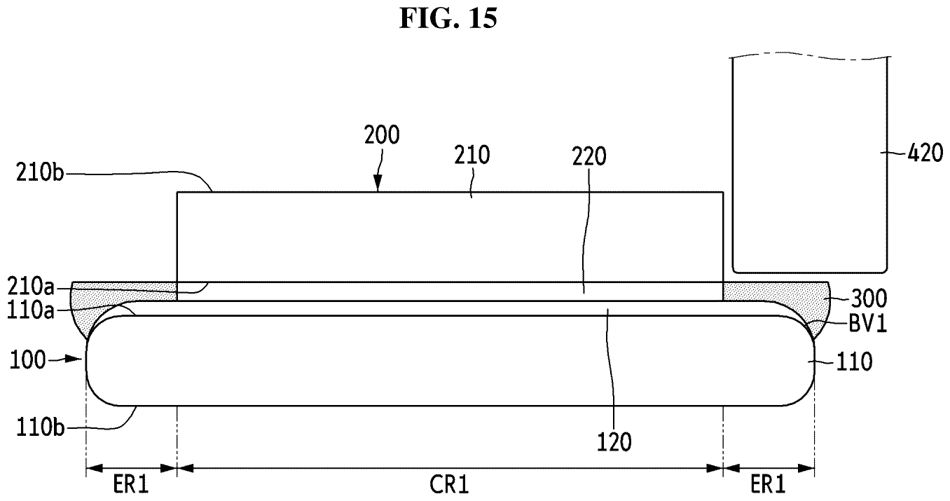

Referring to FIGS. 7 and 15, the trimming process may include a mechanical trimming process.

For example, a blade 420 for performing the trimming process on the second semiconductor substrate 210 may be provided. The blade 420 may remove at least a portion of the second edge region ER2, including the second bevel BV2. In some example embodiments, a portion of the gap-filling film 300 may also be removed by the blade 420.

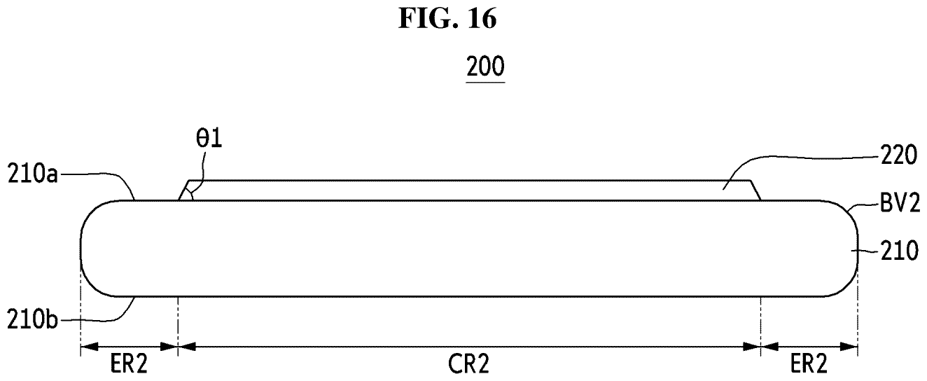

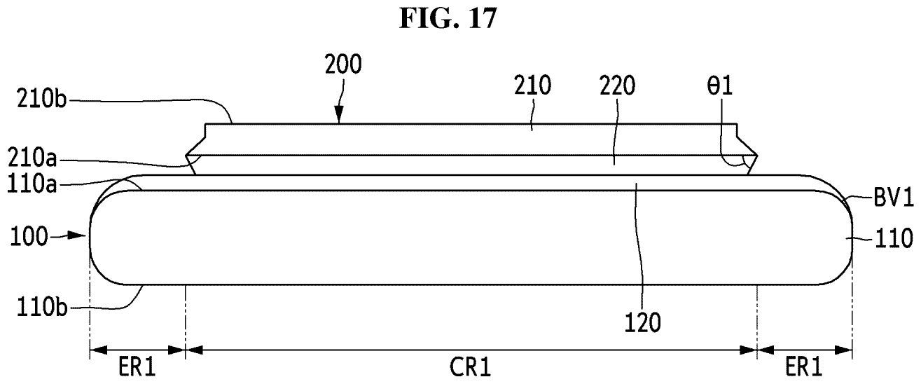

FIGS. 16 and 17 are diagrams illustrating intermediate operations in a method for manufacturing a bonding structure according to some example embodiments. The operations in FIGS. 16 and 17 may be same as or similar in some respects to the operations FIGS. 1 through 15, and therefore may be best understood with reference thereto where like numerals indicate like elements not described again in detail. In some example embodiments, FIG. 16 illustrates an operation subsequent to that illustrated in FIG. 3.

Referring to FIGS. 3 and 16, after the portion of the second semiconductor device layer 220 disposed on the second edge region ER2 is removed, the side surface of the second semiconductor device layer 220 may have an inclined surface.

For example, a first inner angle θ1 formed or defined by the side surface of the second semiconductor device layer 220 with respect to the third surface 210a may be an acute angle. This may result from the characteristics of an etching process applied to the second semiconductor device layer 220. For example, as the etching process is performed on the upper surface of the second semiconductor device layer 220, the side surface of the second semiconductor device layer 220 may form or define an acute first inner angle θ1.

Thereafter, the operations illustrated in FIGS. 5 through 11 may be performed. Through this, a bonding structure illustrated in FIG. 17 may be obtained.

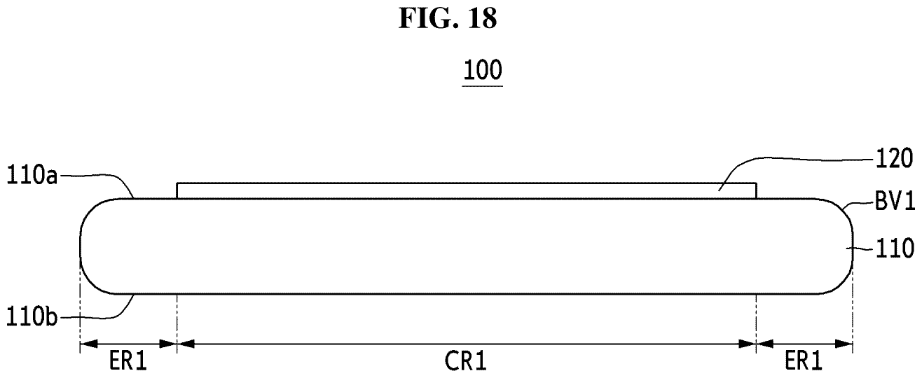

FIGS. 18 through 21 are diagrams illustrating intermediate operations in a method for manufacturing a bonding structure according to some example embodiments. The operations in FIGS. 18 through 21 may be same as or similar in some respects to the operations described above with reference to FIGS. 1 through 17, and therefore may be best understood with reference thereto where like numerals indicate like elements not described again in detail. In some example embodiments, FIG. 18 illustrates an operation subsequent to that illustrated in FIG. 1.

Referring to FIGS. 1 and 18, a portion of the first semiconductor device layer 120 disposed on the first edge region ER1 is removed.

For example, the edge of the first semiconductor device layer 120 disposed on the first edge region ER1 may be removed, exposing the first edge region ER1 from the first semiconductor device layer 120. The portion of the first semiconductor device layer 120 may be removed in a process that may be same as or similar in some respects to the process for removing a portion of the second semiconductor device layer 220, and will be best understood with reference thereto.

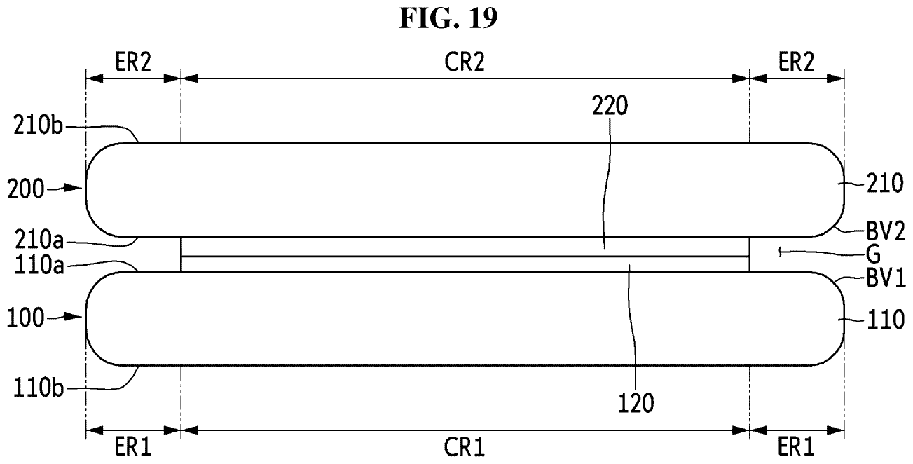

Referring to FIG. 19, the first and second substrate structures 100 and 200 are bonded. The bonding of the first and second substrate structures 100 and 200 may be same as or similar in some respects to that described above with reference to FIGS. 5 and 6, and will be best understood with reference thereto.

Before the bonding of the first and second substrate structures 100 and 200, as the portions of the first and second semiconductor device layers 120 and 220 on the first and second edge regions ER1 and ER2 are removed, the gap G may be formed or otherwise defined between the first and second edge regions ER1 and ER2. Additionally, the gap G may be defined on the side surfaces of the portions of the first and second semiconductor device layers 120 and 220 that remain on the first and second central regions CR1 and CR2.

In some example embodiments, the side surfaces of the first and second semiconductor device layers 120 and 220 may be continuous or flushed. For example, the side surfaces of the first and second semiconductor device layers 120 and 220 may lie in the same plane.

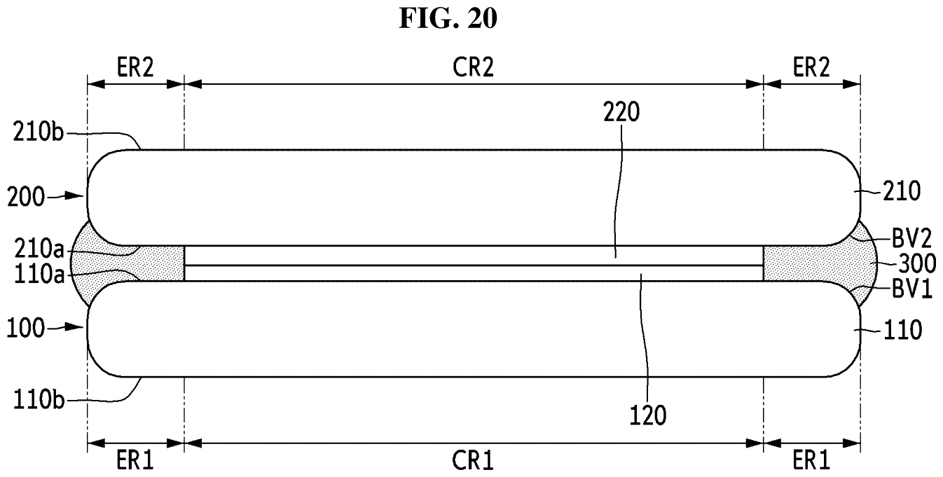

Referring to FIG. 20, the gap-filling film 300 is formed.

The gap-filling film 300 may fill at least a portion of the gap G illustrated in FIG. 19. For example, at least a portion of the gap-filling film 300 may be positioned between the first and second edge regions ER1 and ER2. In some example embodiments, the gap-filling film 300 may contact the first surface 110a of the first semiconductor substrate 110, the side surface of the first semiconductor device layer 120, the side surface of the second semiconductor device layer 220, and the third surface 210a of the second semiconductor substrate 210. In some example embodiments, the gap-filling film 300 may also contact the first and second bevels BV1 and BV2.

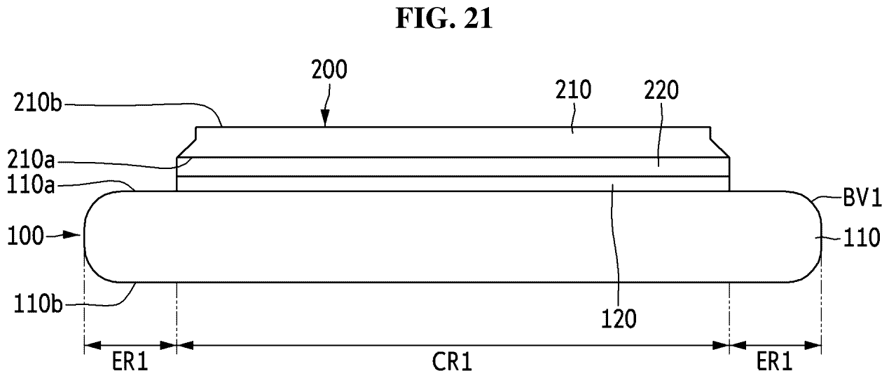

Thereafter, the operations described above with reference to FIGS. 8 through 11 may be performed. Through this, the bonding structure illustrated in FIG. 21 may be obtained.

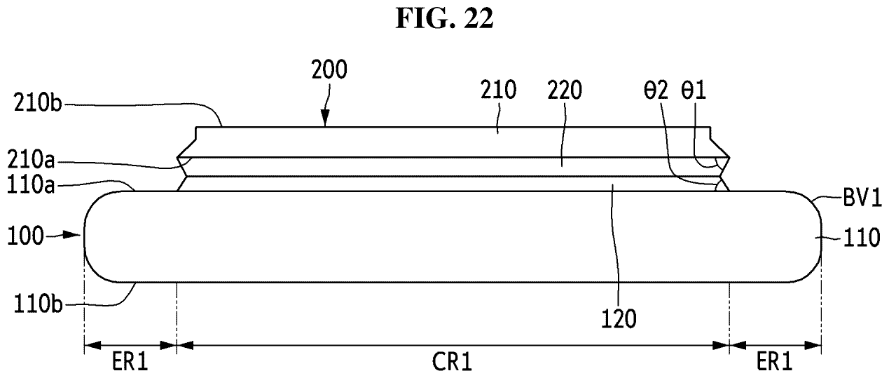

FIGS. 22 through 24 are diagrams illustrating semiconductor devices including different bonding structures according to some example embodiments. The bonding structures in FIGS. 22 through 24 may be best understood with reference to FIGS. 1 through 21.

Referring to FIG. 22, in a bonding structure according to some example embodiments, the side surfaces of first and second semiconductor device layers 120 and 220 may each have an inclined surface.

For example, a second inner angle θ2 formed by the side surface of the first semiconductor device layer 120 with respect to a first surface 110a may be an acute angle. This may result from the characteristics of an etching process applied to the first semiconductor device layer 120. For example, as the etching process is performed on the upper surface of the first semiconductor device layer 120, the side surface of the first semiconductor device layer 120 may form an acute second inner angle θ2.

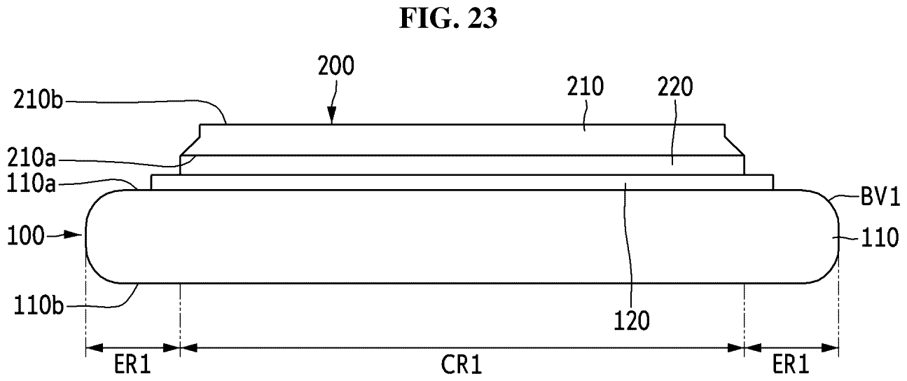

Referring to FIG. 23, in a bonding structure according to some example embodiments, the side surface of a first semiconductor device layer 120 may protrude or extend further horizontally from the side surface of a second semiconductor device layer 220.

For example, the size (or area) of the second semiconductor device layer 220 removed in the etching process for the second semiconductor device layer 220 as described above with reference to FIG. 4 may be greater than the size (or area) of the first semiconductor device layer 120 removed in the etching process for the first semiconductor device layer 120 as described above with reference to FIG. 18. The side surfaces of the first and second semiconductor device layers 120 and 220 may not be continuous or flushed.

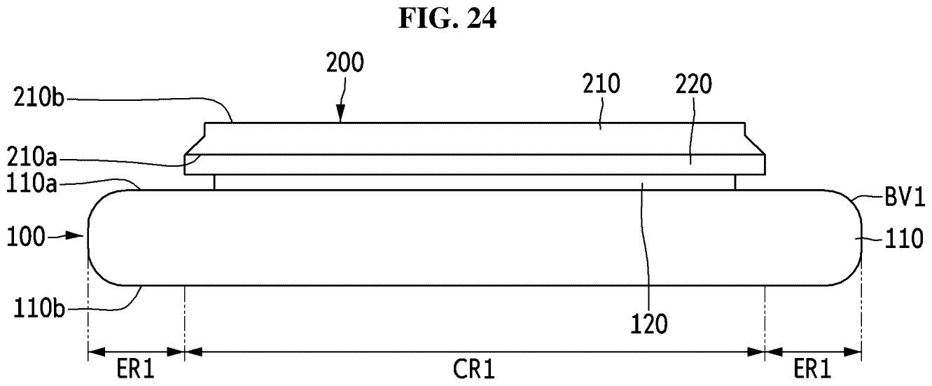

Referring to FIG. 24, in a bonding structure according to some example embodiments, the side surface of the second semiconductor device layer 220 may protrude or extend further in the horizontal direction than the side surface of the first semiconductor device layer 120.

For example, the size (or area) of the first semiconductor device layer 120 removed in the etching process for the first semiconductor device layer 120 as described above with reference to FIG. 18 may be greater than the size (or area) of the second semiconductor device layer 220 removed in the etching process for the second semiconductor device layer 220 as described above with reference to FIG. 4. The side surfaces of the first and second semiconductor device layers 120 and 220 may not be continuous or flushed.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A method for manufacturing a bonding structure, comprising:
providing a first substrate structure including a first semiconductor substrate having a first surface and a second surface that are opposite to each other, and a first semiconductor device layer on the first surface;
providing a second substrate structure including a second semiconductor substrate having a third surface and a fourth surface that are opposite to each other, and a second semiconductor device layer on the third surface;
removing a portion of the second semiconductor device layer disposed on a first edge region of the second semiconductor substrate;
bonding the first and second substrate structures such that the first surface faces the third surface;
forming a gap-filling film that fills at least a portion of a gap between the first substrate structure and the first edge region; and
performing a trimming process to remove at least a portion of the first edge region after the forming the gap-filling film.

2. The method of claim 1, further comprising:
removing a portion of the first semiconductor device layer disposed on a second edge region of the first semiconductor substrate,
wherein the gap-filling film fills at least a portion of a gap between the first and second edge regions.

3. The method of claim 1, wherein a coefficient of thermal expansion (CTE) of the gap-filling film is different from a CTE of the second semiconductor substrate.

4. The method of claim 3, wherein the CTE of the gap-filling film is greater than the CTE of the second semiconductor substrate.

5. The method of claim 1, wherein the removing the portion of the second semiconductor device layer includes at least one of an edge exclusion width (EEW) process, an edge bead removal (EBR) process, or a plasma-enhanced strip (PES) process.

6. The method of claim 1, wherein the trimming process includes a laser trimming process.

7. The method of claim 1, wherein the trimming process includes a mechanical trimming process.

8. The method of claim 1, further comprising:
performing a thinning process to reduce a thickness of the second semiconductor substrate after the performing the trimming process.

9. The method of claim 8, further comprising:
removing the gap-filling film after the performing the thinning process.

10. The method of claim 1, wherein after the removing the portion of the second semiconductor device layer, an inner angle formed by a side surface of the second semiconductor device layer with respect to the third surface is an acute angle.

11. A method for manufacturing a bonding structure, comprising:
providing a first substrate structure including a first semiconductor substrate having a first surface and a second surface that are opposite to each other, and a first semiconductor device layer on the first surface;
providing a second substrate structure including a second semiconductor substrate having a third surface and a fourth surface that are opposite to each other, and a second semiconductor device layer on the third surface;
removing a portion of the second semiconductor device layer disposed on a first edge region of the second semiconductor substrate;
electrically connecting the first and second semiconductor device layers by bonding the first and second substrate structures such that the first surface faces the third surface;
forming a gap-filling film that fills at least a portion of a gap between the first substrate structure and the first edge region;
performing a laser trimming process to remove at least a portion of the first edge region after the forming the gap-filling film; and
performing a thinning process to reduce a thickness of the second semiconductor substrate after performing the laser trimming process,
wherein a coefficient of thermal expansion (CTE) of the gap-filling film is greater than a CTE of the second semiconductor substrate.

12. The method of claim 11, further comprising:
removing a portion of the first semiconductor device layer disposed on a second edge region of the first semiconductor substrate,
wherein the gap-filling film fills at least a portion of the gap between the first and second edge regions.

13. The method of claim 11, wherein the performing the laser trimming process comprises separating the first edge region from a central region of the second semiconductor substrate using a first laser light source, and separating the first edge region from the gap-filling film using a second laser light source different from the first laser light source.

14. The method of claim 11, wherein
the second semiconductor substrate includes monocrystalline silicon, and
the gap-filling film includes polycrystalline silicon.

15. The method of claim 11, further comprising:
removing the gap-filling film after the performing the thinning process.

16. A method for manufacturing a bonding structure, comprising:
providing a first substrate structure including a first semiconductor substrate having a first surface and a second surface that are opposite to each other, and a first semiconductor device layer on the first surface;
removing a portion of the first semiconductor device layer disposed on a first edge region of the first semiconductor substrate;
providing a second substrate structure including a second semiconductor substrate having a third surface and a fourth surface that are opposite to each other, and a second semiconductor device layer on the third surface;
removing a portion of the second semiconductor device layer disposed on a second edge region of the second semiconductor substrate;
electrically connecting the first and second semiconductor device layers by bonding the first and second substrate structures such that the first surface faces the third surface;
forming a gap-filling film that fills at least a portion of a gap between the first and second edge regions;
performing a trimming process to remove at least a portion of the second edge region after the forming the gap-filling film; and
performing a thinning process to reduce a thickness of the second semiconductor substrate after the performing the trimming process.

17. The method of claim 16, wherein the trimming process includes a laser trimming process.

18. The method of claim 16, wherein the trimming process includes a mechanical trimming process.

19. The method of claim 16, further comprising:
removing the gap-filling film after the performing the thinning process.

20. The method of claim 16, wherein
the removing the portion of the first semiconductor device layer includes removing the portion of the first semiconductor device layer such that an inner angle formed by a side surface of the first semiconductor device layer with respect to the first surface is an acute angle; and
the removing the portion of the second semiconductor device layer includes removing the portion of the second semiconductor device layer such that an inner angle formed by a side surface of the second semiconductor device layer with respect to the third surface is an acute angle.
